(19) United States
(12) Patent Application Publication
(10) Pub. No.: US 2025/0231241 A1
(43) Pub. Date: Jul. 17, 2025

(54) BATTERY CELL EVALUATION BASED ON EQUIVALENT CIRCUIT MODEL

(71) Applicant: GM Global Technology Operations LLC, Detroit, MI (US)

(72) Inventor: Yangbing Zeng, Troy, MI (US)

(21) Appl. No.: 18/413,549

(22) Filed: Jan. 16, 2024

(51) Int. Cl. G01R 31/367; B60L 58/12; B60R 16/033; G01R 31/3842

(52) U.S. Cl. CPC G01R 31/367; B60R 16/033; G01R 31/3842; B60L 58/12

(57) ABSTRACT

A system for evaluating a battery assembly includes an acquisition module configured to acquire parameters related to a battery assembly, and an evaluation module configured to acquire an equivalent circuit model representing a battery cell of the battery assembly and run the equivalent circuit model to simulate charging and discharging. The equivalent circuit model includes an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell.

### INTRODUCTION

The subject disclosure relates to batteries, and more specifically to modelling battery cells.

Vehicles, including gasoline and diesel power vehicles, as well as electric and hybrid electric vehicles, feature battery storage for purposes such as powering electric motors, electronics and other vehicle subsystems. Battery system monitoring is an important aspect of battery operation. For example, estimations of battery state of charge (SOC) and state of health (SOH) are used during battery operation for purposes such as cell balancing, thermal regulation and maintaining desired operating parameters. Circuit models are often used in such estimations and for monitoring and battery evaluations.

### SUMMARY

In one exemplary embodiment, a system for evaluating a battery assembly includes an acquisition module configured to acquire parameters related to a battery assembly, and an evaluation module configured to acquire an equivalent circuit model representing a battery cell of the battery assembly and run the equivalent circuit model to simulate charging and discharging. The equivalent circuit model includes an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell.

In addition to one or more of the features described herein, each respective time constant range is selected based on a physics-based model that describes charge transport within the battery cell.

In addition to one or more of the features described herein, each respective time constant range is associated with a response of the battery cell at a state of charge (SOC).

In addition to one or more of the features described herein, the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

In addition to one or more of the features described herein, each assigned time constant range is selected based on a physics-based model of the battery cell, the physics-based model configured to simulate electrochemical phenomena related to diffusion of ions and electrons within the battery cell.

In addition to one or more of the features described herein, the physics-based model simulates ion concentration via a set of differential equations, and each assigned time constant range is selected based on one of the set of the differential equations.

In addition to one or more of the features described herein, the first time constant range is based on a fast response of the battery cell, the second time constant range is based on a liquid diffusion, and the third time constant range is based on a solid diffusion.

In addition to one or more of the features described herein, the battery assembly is at least one of a battery module and a battery pack of a vehicle.

In another exemplary embodiment, a method of evaluating a battery assembly includes acquiring parameters related to a battery assembly, and simulating responses of a battery cell of the battery assembly to charging and/or discharging using an equivalent circuit model representing the battery cell. The equivalent circuit model includes an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell. The method also includes, based on the simulated responses, performing at least one of: designing the battery assembly, monitoring the battery assembly, and controlling operation of the battery assembly.

In addition to one or more of the features described herein, each respective time constant range is selected based on a physics-based model that describes charge transport within a battery cell of the battery assembly.

In addition to one or more of the features described herein, each respective time constant range is associated with a response of the battery cell at a state of charge (SOC).

In addition to one or more of the features described herein, the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

In addition to one or more of the features described herein, the battery assembly is a lithium-based battery assembly configured for use in a vehicle, the first time constant range is about zero seconds to about 2 seconds, the second time constant range is about 2 seconds to about 32 seconds, and the third time constant range is about 32 seconds to about 512 seconds.

In addition to one or more of the features described herein, each assigned time constant range is selected based on a physics-based model of the battery cell, the physics-based model configured to simulate electrochemical phenomena related to diffusion of ions and electrons within the battery cell.

In addition to one or more of the features described herein, the first time constant range is based on a fast response of the battery cell, the second time constant range is based on a liquid diffusion, and the third time constant range is based on a solid diffusion.

In addition to one or more of the features described herein, the battery assembly is at least one of a battery module and a battery pack of a vehicle.

In yet another exemplary embodiment, a vehicle system includes a memory having computer readable instructions, and a processing device for executing the computer readable instructions, the computer readable instructions controlling the processing device to perform a method. The method includes acquiring parameters related to a battery assembly, and simulating responses of a battery cell of the battery assembly to charging and/or discharging using an equivalent circuit model representing the battery cell, the equivalent circuit model including an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell. The method also includes, based on the simulated responses, performing at least one of: designing the battery assembly, monitoring the battery assembly, and controlling operation of the battery assembly.

In addition to one or more of the features described herein, the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

In addition to one or more of the features described herein, each assigned time constant range is selected based on a physics-based model of the battery cell, the physics-based model configured to simulate electrochemical phenomena related to diffusion of ions and electrons within the battery cell.

In addition to one or more of the features described herein, the first time constant range is based on a fast response of the battery cell, the second time constant range is based on a liquid diffusion, and the third time constant range is based on a solid diffusion.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a top view of a motor vehicle including a battery assembly, in accordance with an exemplary embodiment;

FIG. 2 depicts an equivalent circuit model of a battery cell, in accordance with an exemplary embodiment;

FIG. 3 depicts an example of result of a simulation of a battery assembly using a physics-based model of a battery cell, and an example of a simulation result using an equivalent circuit model in accordance with an exemplary embodiment;

FIG. 4 is a flow diagram depicting aspects of a method of evaluating a battery cell and/or battery assembly, in accordance with an exemplary embodiment; and

FIG. 5 depicts a computer system in accordance with an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Devices, systems and methods are provided for monitoring and/or evaluating a battery cell and/or a battery assembly using equivalent circuit electrochemical modeling. An embodiment of a battery monitoring or evaluation system is configured to generate or acquire an equivalent circuit model of a battery cell, for use in simulating electrochemical processes in the battery cell. The equivalent circuit model includes at least three resistance-capacitance (R-C) pairs, in which each R-C pair includes a resistance connected in parallel to a capacitance. Each pair is associated with a time constant selected from a range of time constants. The range of time constants for an R-C pair is selected based on physical properties and physics-related behaviors. For example, each time constant range is selected using a physics-based model that accounts for battery chemistry, electrode dimension and properties and/or other physical properties and phenomena. Equivalent circuit models as described herein can be used for a variety of purposes, such as battery monitoring during operation, health evaluation, state prediction, state of charge estimation and others.

Embodiments described herein present numerous advantages and technical effects. The embodiments provide for effective monitoring and evaluation of battery assemblies, such as vehicle battery systems, using improved equivalent circuit models. Such equivalent circuit models provide for more accurate simulations of battery assemblies, allowing for more effective SOC and SOH estimations, more precise battery control and improvements in battery monitoring systems of electric and hybrid vehicles.

Equivalent circuit models described herein provide for an improvement over existing models. For example, standard equivalent circuit models generally have good accuracy for short pulse operation (e.g., city driving) but are less accurate for long pulse operation (e.g., direct current fast charging (DCFC)). In another words, standard equivalent circuit models cannot fully capture all relevant or desired time scales. Embodiments described herein provide for equivalent circuit models that can cover all relevant time scales, or otherwise cover all desired time scales, and thus have good accuracy for both short pulse and long pulse operations. This is critical to accurately predict battery response during operation, in order to properly account for instant power (which is largely determined by short response) and heat generation during DCFC (which is largely determined by long response).

The embodiments are not limited to use with any specific vehicle and may be applicable to various contexts. For example, embodiments may be used with automobiles, trucks, aircraft, construction equipment, farm equipment, automated factory equipment and/or any other device or system that utilizes rechargeable energy storage systems.

FIG. 1 shows an embodiment of a motor vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine system 18 and at least one electric motor assembly. In an embodiment, the propulsion system 16 includes an electric motor 20, and may include one or more additional motors positioned at various locations. The vehicle 10 may be a fully electric vehicle having one or more electric motors.

The vehicle 10 includes a battery system 22, which may be electrically connected to the motor 20 and/or other components, such as vehicle electronics. The battery system 22 may be configured as a rechargeable energy storage system (RESS). In an embodiment, the battery system 22 includes a battery assembly such as a high voltage battery pack 24 having a plurality of battery modules 26. The battery system 22 may also include a monitoring unit 28 that includes components such as a processor, memory, an interface, a bus and/or other suitable components.

It is noted that a “battery assembly” may be a single battery cell or a group of cells. For example, the battery assembly may be the battery pack 24, a battery module 26 or an individual cell or group of cells in a module 26.

Each battery module includes a plurality of cells (not shown) having a selected chemistry. In an embodiment, each cell is a lithium-ion battery, such as a lithium ferro-phosphate (LFP) battery or lithium nickel manganese colbalt oxide (NCM) battery. The battery pack 24 is not so limited and can have any suitable chemistry. Other examples include nickel-metal hydride and lead acid chemistries.

The battery system 22 is electrically connected to components of the propulsion system 16. The propulsion system also includes an inverter module 30 and a direct current (DC)-DC converter module 32. The inverter module 30 (e.g., a traction power inverter unit or TPIM) converts DC power from the battery system 22 to poly-phase alternating current (AC) power (e.g., three-phase, six-phase, etc.) to drive the motor 20.

Various control modules (electronic control modules or ECMs) may be included in the vehicle 10. For example, an auxiliary power module (APM) 34 is included for providing power to accessories (e.g., 12V loads). An on-board charger module (OBCM) 36 may be included, which connects the battery system 22 to a charge port 38, and controls aspects of charging the battery system 22 (e.g., from a charging station, grid or other vehicle) and/or providing charge to an external system.

The vehicle 10 also includes a computer system 40 that includes one or more processing devices 42 and a user interface 44. The various processing devices and units may communicate with one another via a communication device or system, such as a controller area network (CAN) or transmission control protocol (TCP) bus.

One or more processing devices are configured to monitor and/or evaluate a battery assembly, such as the battery pack 24. Such monitoring and evaluation can be used to control battery operation, identify faults, monitor battery health, monitor aging, perform battery testing, design and others. An embodiment of an evaluation system includes a processing device, such as a processing device in the vehicle 10 (e.g., the OBCM 36, the monitoring unit 28 and/or an RESS controller), that acquires measurements of the battery pack 24 over time.

In an embodiment, the one or more processing devices acquire or generate an equivalent circuit model, which electrically represents charging and discharging characteristics of a battery cell. The equivalent circuit model includes a voltage source and current, as well as a set of resistor-capacitor (R-C) pairs. In an embodiment, the equivalent circuit model is a cell-level model.

Parameters of the equivalent circuit model include voltage, resistance and ranges of the R-C pairs. Other parameters include C-rate, permitted voltage ranges and others, which can be determined based on empirical data or manufacturer information.

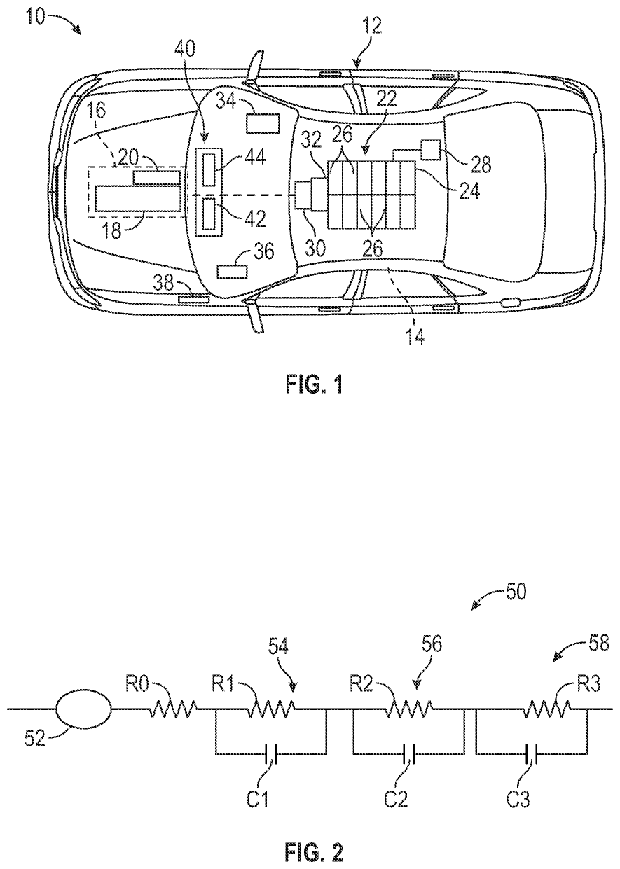

FIG. 2 depicts an embodiment of an equivalent circuit model 50, which includes an open circuit voltage (OCV) 52 at a given state of charge (SOC), an internal ohmic resistance R0, and three R-C pairs 54, 56 and 58. Each R-C pair is a parallel R-C network, in which resistances and capacitances described the transient response during charging and discharging. A first R-C pair includes a resistance R1 connected in parallel to a capacitance C1, a second R-C pair includes a resistance R2 connected in parallel to a capacitance C2, and a third R-C pair includes a resistance R3 connected in parallel to a capacitance C3.

In this embodiment, each time constant is selected from a time constant range associated with each R-C pair. For example, the first R-C pair 54 is assigned a first time constant, the second R-C pair 56 is assigned a second time constant, and the third R-C pair 56 is assigned a third time constant. In an embodiment, each R-C pair is assigned a different time constant to account for different electrochemical phenomena, such as diffusion in either electrolyte or electrode.

Each R-C pair is assigned a time constant from a respective time constant range. The time constant ranges are selected based on physical properties of a battery cell, including chemistry, as well as physics-based behaviors or phenomena. In an embodiment, a mathematical physics-based model is used to determine the time constant ranges.

The mathematical model simulates electrochemical and physical processes that occur when a battery cell is being charged and/or discharged. In an embodiment, the model is a physics-based model of a lithium-ion battery cell (or other chemistry). Examples of such models include microscale models, pseudo three-dimensional models (P3Ds), pseudo two-dimensional models (P2D), single particle models (SPMs) and SPMe (SPM with electrolyte). These models describe key electrochemical and physical process using mathematical equations with some different levels of approximation, in order to achieve desired tradeoff between computation cost and accuracy.

In an embodiment, a P2D model is used to determine ranges of time constants. This model is also referred to as a Doyle-Fuller-Newman (DFN) model or Newman model. The P2D model describes transport of lithium ions, cell thermodynamics and kinetics within a lithium ion battery cell. Although the P2D model can be directly solved, there are situations in which directly solving such a model is infeasible or impractical. For example, limitations in processing speed and memory make directly solving a P2D model onboard (i.e., using vehicle onboard computer capability) is not practical. The equivalent circuit models and associated methods described herein require significantly less computing power and storage, allowing for effective onboard computation and thereby circumventing this limitation.

In an embodiment, the P2D model simulates electrochemical processes based on a simulation of a lithium-ion cell. The cell includes a porous anode and cathode, which are made from solid active materials that can store lithium intercalated in the solid material. The anode is connected to an anode current collector and the cathode is connected to a cathode current collector. A separator is disposed between the anode and the cathode, and allows the passage of ions but not electrons. The porous electrodes and the separator are soaked in an electrolyte, which allows the transport of ions. During discharge, lithium stored in the anode is released as ions in the electrolyte. Driven by diffusion (concentration gradient) and migration (electric potential gradient), lithium ions travel through the separator to the cathode where they are inserted in the lattice of the cathode active material. Simultaneously, electrons travel from the anode to the cathode through an external circuit. These processes are reversed during battery charging.

The P2D model simulates a battery cell and the processes, and accounts for a number of variables. The variables are related to lithium ion concentration and transport, temperature, electrical potential and other phenomena. Ion transport in electrolyte and/or lithium intercalation in electrode material can be very well described by a diffusion equation. The time constants for a diffusion equation can be derived from its coefficients.

In an embodiment, the time constants derived from the P2D model are used as time constants assigned to each R-C pair in the equivalent circuit model. Each time constant is associated with a respective equilibrium response. The diffusion equation may have any number of time constants to account for electrode and/or electrolyte diffusion and transport properties.

For example, the P2D model is analyzed to determine diffusion behaviors using one or more differential equations. The time constants associated with the R-C pairs 54, 56 and 58 are selected as the time constants associated with the three highest equilibrium responses of the differential equations.

The following are diffusion equations for an example of a P2D model. It is noted that this example is not intended to be limiting, as other differential equations representing other processes (e.g., electrolyte transport) may be used.

In this example, the P2D model represents host intercalation materials (e.g., lithium-cobalt oxide and graphite) as spherical particles having radii in a radial direction r. Positions at the spherical particles are described according to a length dimension x, where x=0 at a center of active material particle, and x=R at surface of the active material particle. The diffusion equations describe changes in solid-phase surface concentration C over time as a function of r and time t:

$$\frac{\partial C}{\partial t} = \frac{1}{{r}^{2}} \frac{1}{\partial r} ( {r}^{2} D \frac{\partial C}{\partial r} )$$

$$\frac{\partial C}{\partial r} ( r = 0 ) = 0$$

$$\frac{\partial C}{\partial r} ( r = R ) = \frac{J}{D} .$$

In these equations, D is a constant solid-phase diffusion coefficient. J is electrode current density, and R is radius of a particle in the radial dimension r.

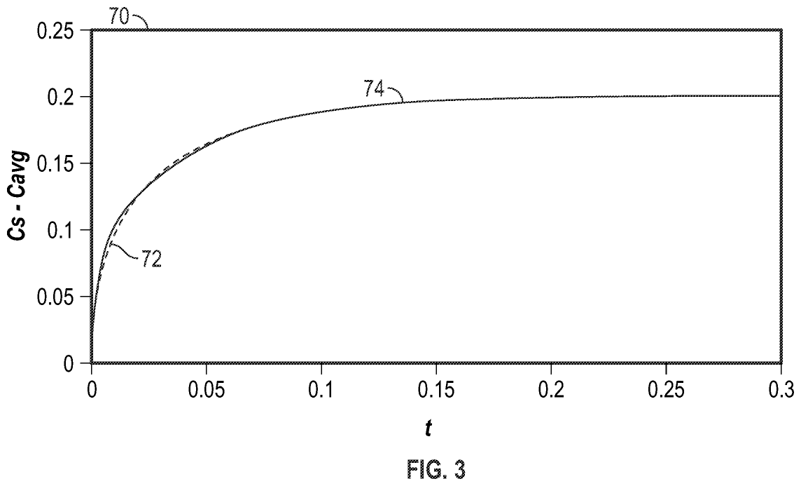

FIG. 3 depicts an example of a solution of the above differential equations, in which two time constants (0.0035R²/D and 0.0434 R²/D) and two equilibrium responses (0.0816 JR/D and 0.1184 JR/D) were derived. It is noted that any number of constants and responses can be derived by analyzing various sub-processes simulated by the model.

The differential equations, including the derived constants and responses, describe intercalation processes. The spatial dimension r is discretized, such that the surface concentration Cₛ is split into components Cₘ, Cₛₘ₁ and Cₛₘ₂, where Cₛ=Cₘ+Cₛₘ₁+Cₛₘ₂. The differential equations in this example include the following:

$$\frac{{dC}_{m}}{dt} = \frac{3 J}{R}$$

$$\frac{{dC}_{sm 1}}{dt} = \frac{0.0816 J R / D - {C}_{sm 1}}{0.0035 {R}^{2} / D}$$

$$\frac{{dC}_{sm 2}}{dt} = \frac{0.1184 J R / D - {C}_{sm 2}}{0.0434 {R}^{2} / D}$$

$${C}_{s} = {C}_{sm 1} + {C}_{sm 2} + {C}_{m} .$$

FIG. 3 is a graph 70 of surface concentration as a function of time t (in seconds). The surface concentration is represented as a difference between Cₛ and C_{avg} (in normalized units). C_{avg} is an average concentration in a particle. A curve 72 shows the solution of the above differential equations. A curve 74 shows the results of solving an equivalent circuit model using the time constants for the R-C pairs. As shown, there is very good agreement between the solution of a P2D model and the equivalent circuit model.

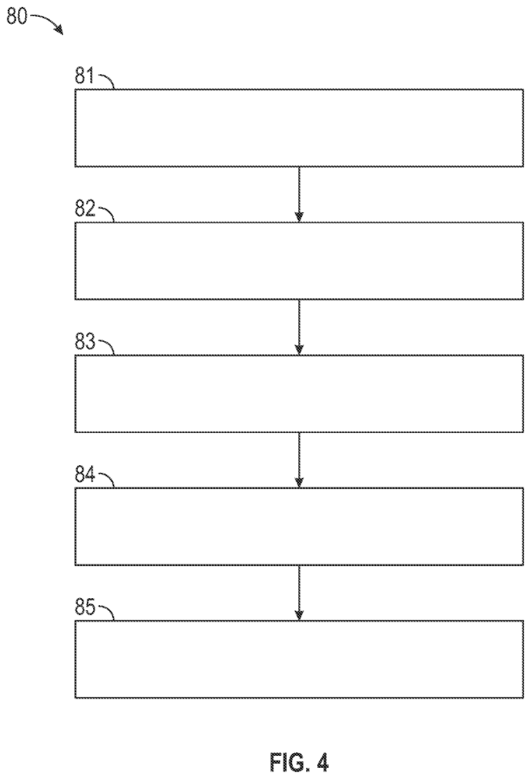

FIG. 4 illustrates embodiments of a method 80 of evaluating a battery assembly (e.g., the battery pack 24). Aspects of the method 80 may be performed by a processor or processors disposed in the vehicle 10 (e.g., the monitoring unit 28, the computer system 40, etc.). It is noted that the method 80 is not so limited and may be performed by any suitable processing device or system, or combination of processing devices. In addition, the method 80 is not limited to use with the vehicle 10, as the method 80 may be performed in conjunction with any suitable battery or battery system.

The method 80 includes a number of steps or stages represented by blocks 81-85. The method 80 is not limited to the number or order of steps therein, as some steps represented by blocks 81-85 may be performed in a different order than that described below, or fewer than all of the steps may be performed.

At block 81, a processing device collects properties and characteristics of a battery assembly. Such collection may be realized by performing measurements and acquiring properties of an existing battery assembly (e.g., chemistry, C-rate, voltage parameters, etc.). Alternatively, collection may be realized by acquiring information describing a proposed design of a battery assembly.

For example, measurements of voltage, current and/or other parameters are performed at a plurality of measurement times or sample times. “Monitoring” as described herein refers to performing various measurements of a battery assembly in a given context.

For example, monitoring may occur by taking measurements of the battery pack 24 during operation of the vehicle 10, between periods of operation and at other times desired to determine battery parameters or otherwise evaluate the battery pack. Monitoring may also include performing measurements during diagnostic testing, testing during or after manufacturing, and laboratory testing.

At block 82, an equivalent circuit model of the battery system is acquired. Acquisition of the equivalent circuit model may include receiving a previously generated equivalent circuit model, updating a previously generated equivalent circuit model or generating a new equivalent circuit model.

For example, the equivalent circuit model is generated by collecting battery characteristics, including chemistry, electrode properties and others. Voltage and current responses may be analyzed to determine parameters of the equivalent circuit model. In an embodiment, the parameters include OCV at various SOCs (e.g., from an OCV-SOC curve), C-rate, voltage range and others.

In an embodiment, the equivalent circuit model is a cell-level model having at least three R-C pairs for simulating various electrochemical processes. The method 80 is discussed in conjunction with the equivalent circuit model 50 of FIG. 2, but is not so limited, as the model may have fewer than three or more than three pairs.

At block 83, a time constant range is selected for each R-C pair 54, 56 and 58. In an embodiment, a physics-based model is run to determine physical and electrochemical characteristics that are used to determine the time constant ranges.

For example, a P2D model or other suitable physics-based model is run to determine electrochemical characteristics of the battery assembly (e.g., the battery pack 24). Such characteristics include fast response time, and diffusion behaviors including fast diffusion (e.g., liquid diffusion) and slow diffusion (e.g., solid diffusion).

In this example, a first time constant range is assigned to the first R-C pair 52, so as to equal or encompass fast responses determined using the physics-based model. An example of a time constant range for the first R-C pair 54 is about zero to about two seconds.

A second time constant range is assigned to the second R-C pair 56, so as to equal or encompass fast diffusion times determined using the physics-based model. An example of a time constant range for the second R-C pair 56 is about two seconds to about 32 seconds.

A third time constant range is assigned to the third R-C pair 58, so as to equal or encompass slow diffusion times determined using the physics-based model. An example of a time constant range for the third R-C pair 58 is about 32 seconds to about 512 seconds or more.

At block 84, the equivalent circuit model is executed to simulate a battery cell response to input voltages and currents. For example, the model is repeatedly run for a set of charging and/or discharging pulses. The pulse length is selected based on a desired operation, such as providing power for vehicle propulsion, charging (e.g., Level 1, Level 2, Level 3 (DCFC), etc.), thermal management (e.g., applying a pulsed heating current.

At block 85, various actions can be performed based on the results of the simulation. Such actions include modeling and simulation for use in designing battery assemblies. Other actions include controlling operation of a battery assembly, monitoring a battery assembly, performing diagnostics, performing prognosis, predicting heat generation for thermal management control and others. For example, the equivalent circuit model 50 is used during operation of the vehicle 10 and the battery pack 24 to estimate battery parameters such as SOC and SOH, and the vehicle 10 is controlled based on the estimated battery parameters (e.g., by controlling propulsion, controlling electrical loads in the vehicle, shutting down, etc.)

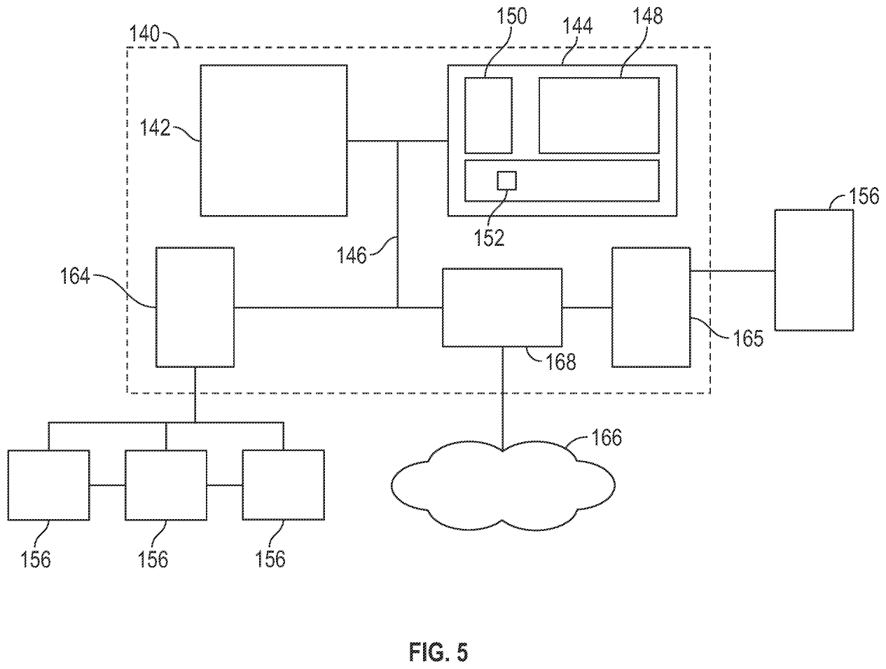

FIG. 5 illustrates aspects of an embodiment of a computer system 140 that can perform various aspects of embodiments described herein. The computer system 140 includes at least one processing device 142, which generally includes one or more processors for performing aspects of image acquisition and analysis methods described herein.

Components of the computer system 140 include the processing device 142 (such as one or more processors or processing units), a memory 144, and a bus 146 that couples various system components including the system memory 144 to the processing device 142. The system memory 144 can be a non-transitory computer-readable medium, and may include a variety of computer system readable media. Such media can be any available media that is accessible by the processing device 142, and includes both volatile and non-volatile media, and removable and non-removable media.

For example, the system memory 144 includes a non-volatile memory 148 such as a hard drive, and may also include a volatile memory 150, such as random access memory (RAM) and/or cache memory. The computer system 140 can further include other removable/non-removable, volatile/non-volatile computer system storage media.

The system memory 144 can include at least one program product having a set (e.g., at least one) of program modules that are configured to carry out functions of the embodiments described herein. For example, the system memory 144 stores various program modules that generally carry out the functions and/or methodologies of embodiments described herein. A module or modules 152 may be included to perform functions related to acquiring OCV, SOC and other battery assembly measurements, and battery evaluation as discussed herein. The system 140 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 142 can also communicate with one or more external devices 156 as a keyboard, a pointing device, and/or any devices (e.g., network card, modem, etc.) that enable the processing device 142 to communicate with one or more other computing devices. Communication with various devices can occur via Input/Output (I/O) interfaces 164 and 165.

The processing device 142 may also communicate with one or more networks 166 such as a local area network (LAN), a general wide area network (WAN), a bus network and/or a public network (e.g., the Internet) via a network adapter 168. It should be understood that although not shown, other hardware and/or software components may be used in conjunction with the computer system 140. Examples include, but are not limited to: microcode, device drivers, redundant processing units, external disk drive arrays, RAID systems, and data archival storage systems, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A system for evaluating a battery assembly, comprising:
an acquisition module configured to acquire parameters related to a battery assembly; and
an evaluation module configured to acquire an equivalent circuit model representing a battery cell of the battery assembly and run the equivalent circuit model to simulate charging and discharging, the equivalent circuit model including an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell.

2. The system of claim 1, wherein each respective time constant range is selected based on a physics-based model that describes charge transport within the battery cell.

3. The system of claim 1, wherein each respective time constant range is associated with a response of the battery cell at a state of charge (SOC).

4. The system of claim 1, wherein the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

5. The system of claim 4, wherein each assigned time constant range is selected based on a physics-based model of the battery cell, the physics-based model configured to simulate electrochemical phenomena related to diffusion of ions and electrons within the battery cell.

6. The system of claim 5, wherein the physics-based model simulates ion concentration via a set of differential equations, and each assigned time constant range is selected based on one of the set of the differential equations.

7. The system of claim 5, wherein the first time constant range is based on a fast response of the battery cell, the second time constant range is based on a liquid diffusion, and the third time constant range is based on a solid diffusion.

8. The system of claim 1, wherein the battery assembly is at least one of a battery module and a battery pack of a vehicle.

9. A method of evaluating a battery assembly, comprising:
acquiring parameters related to a battery assembly;
simulating responses of a battery cell of the battery assembly to charging and/or discharging using an equivalent circuit model representing the battery cell, the equivalent circuit model including an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell; and
based on the simulated responses, performing at least one of: designing the battery assembly, monitoring the battery assembly, and controlling operation of the battery assembly.

10. The method of claim 9, wherein each respective time constant range is selected based on a physics-based model that describes charge transport within a battery cell of the battery assembly.

11. The method of claim 9, wherein each respective time constant range is associated with a response of the battery cell at a state of charge (SOC).

12. The method of claim 9, wherein the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

13. The method of claim 12, wherein the battery assembly is a lithium-based battery assembly configured for use in a vehicle, the first time constant range is about zero seconds to about 2 seconds, the second time constant range is about 2 seconds to about 32 seconds, and the third time constant range is about 32 seconds to about 512 seconds.

14. The method of claim 12, wherein each assigned time constant range is selected based on a physics-based model of the battery cell, the physics-based model configured to simulate electrochemical phenomena related to diffusion of ions and electrons within the battery cell.

15. The method of claim 14, wherein the first time constant range is based on a fast response of the battery cell, the second time constant range is based on a liquid diffusion, and the third time constant range is based on a solid diffusion.

16. The method of claim 9, wherein the battery assembly is at least one of a battery module and a battery pack of a vehicle.

17. A vehicle system comprising:
a memory having computer readable instructions; and
a processing device for executing the computer readable instructions, the computer readable instructions controlling the processing device to perform a method including:
acquiring parameters related to a battery assembly;
simulating responses of a battery cell of the battery assembly to charging and/or discharging using an equivalent circuit model representing the battery cell, the equivalent circuit model including an open circuit voltage (OCV), an internal resistance, and three resistor-capacitor (R-C) pairs, each R-C pair being a parallel R-C network connected in series to the internal resistance, each R-C pair having a time constant selected from a respective time constant range, each respective time constant range selected based on estimations of physical phenomena associated with operation of the battery cell; and
based on the simulated responses, performing at least one of: designing the battery assembly, monitoring the battery assembly, and controlling operation of the battery assembly.

18. The vehicle system of claim 17, wherein the R-C pairs include a first R-C pair assigned a first time constant range, a second R-C pair assigned a second time constant range and a third R-C pair assigned a third time constant range, wherein the first time constant range, the second time constant range and the third time constant range each have a different temporal value.

19. The vehicle system of claim 18, wherein each assigned time constant range is selected based on a physics-based model of the battery cell, the physics-based model configured to simulate electrochemical phenomena related to diffusion of ions and electrons within the battery cell.

20. The vehicle system of claim 19, wherein the first time constant range is based on a fast response of the battery cell, the second time constant range is based on a liquid diffusion, and the third time constant range is based on a solid diffusion.
